(19) United States
(12) Patent Application Publication
(10) Pub. No.: US 2016/0211112 A1
(43) Pub. Date: Jul. 21, 2016

(54) Method and Apparatus for Reviewing Defects

(71) Applicant: Hitachi High-Technologies Corporation, Tokyo (JP)

(72) Inventors: Toshiyuki NAKAO, Tokyo (JP); Yuko OTANI, Tokyo (JP); Takehiro HIRAI, Tokyo (JP)

(21) Appl. No.: 14/995,813

(22) Filed: Jan. 14, 2016

(30) Foreign Application Priority Data
Jan. 16, 2015 (JP) 2015-006389

(51) Int. Cl. H01J 37/22; H01J 37/285

(52) U.S. Cl. CPC H01J 37/222; H01J 37/285; H01J 37/226

(57) ABSTRACT

A defect reviewing apparatus includes an illumination optical system that irradiates a sample with laser, a detection optical system that detects reflected light or scattered light from the sample, a processing portion that calculates coordinates of a defect based on the reflected light or scattered light detected, and an electron microscope that reviews the defect based on the coordinates of the defect calculated by the processing portion. In the illumination optical system, inspection modes are switched over based on defect information acquired in another inspection equipment.

### INCORPORATION BY REFERENCE

The present application claims priority from Japanese application JP-2015-006389 filed on Jan. 16, 2015, the content of which is hereby incorporated by reference into this application.

### BACKGROUND OF THE INVENTION

The present application relates to a method and an apparatus for reviewing defects and the like that are generated on a semiconductor wafer in a manufacturing process for a semiconductor device to be reviewed at high speed with high resolution.

If foreign substances or pattern defects such as short circuits or wire breaks (hereinafter foreign substances and/or pattern defects are generally referred to as defects) exist on a wafer that is a semiconductor substrate, malfunctions such as insulation failure and short circuit of wiring would occur. Since these defects are introduced into a wafer due to various causes that arises in the manufacturing process, it is important to detect defects at earlier stages that are generated in the manufacturing process, trace their sources, and prevent reduction of yield for the mass production of semiconductor devices.

A widely practiced identification method of sources of defect generation will be described. In the first place, a location of a defect on a wafer is identified with a defect inspection equipment and the corresponding defect is observed in detail with a scanning electron microscope (SEM) or the like and categorized based on its coordinate information so that it is compared with data stored in a database to estimate a cause of generation of the defect. However, since there is a deviation between the coordinate system of the SEM and that of another inspection equipment, a method of re-inspecting the defect detected with the other inspection equipment with an optical microscope with which the SEM is equipped, correcting the coordinate information, and reviewing the defect in detail based on the corrected coordinate information is used. Accordingly, the deviation in the different coordinate systems can be corrected and the success rate of defect observation can be improved, thereby maintaining a high throughput. JP-B-4979246 discloses a defect reviewing apparatus that is equipped with an optical microscope and a scanning electron microscope.

### SUMMARY OF THE INVENTION

As semiconductor devices have been miniaturized and highly integrated, not only patterns formed on wafers have been further miniaturized but the sizes of defects that are critical to semiconductor devices have been also miniaturized. As the sizes of defects are miniaturized, amounts of reflected light and scattered light originated from the defects decrease and they are likely to be buried in noises to fail to be detected; thus, they need to be increased. There exist, as the techniques for increasing the amount of scattered light by defects, shortening the wavelength and/or increasing the output of illumination light, increasing a detection solid angle of a detection optical system, increasing an exposure time period of a detector, or the like; however, they would cause the cost of the equipment to rise and/or the throughput to decrease. In contrast to these techniques, increase in the illumination intensity by reduction of the illumination spot would not cause such the disadvantages and, thus, it would be an effective technique to increase the amount of scattered light by a defect in defect detection. However, when the illumination spot is decreased in the apparatus configuration described in JP-B-4979246, it is possible that the field of view becomes narrow and defects may be overlooked. Therefore, the present application is to provide a method and an apparatus for reviewing defects that allow an optical microscope installed to an SEM to accommodate inspections with high sensitivity and prevention of defects from being overlooked.

In order to solve the above problem, provided in the present application is a defect reviewing apparatus, including: an illumination optical system that irradiates a sample with laser, inspection modes being switched over in the illumination optical system based on defect information acquired in another inspection equipment; a detection optical system that detects reflected light or scattered light from the sample; a processing portion that calculates coordinates of a defect based on the reflected light or scattered light detected by the detection optical system; and an electron microscope that reviews the defect based on the coordinates of the defect calculated by the processing portion.

The present application can provide a method and an apparatus for reviewing defects that allow microscopic defects to be reviewed with high accuracy.

Other objects, features, and advantages of the invention will become apparent from the following description of the embodiments of the invention taken in conjunction with the accompanying drawings.

### BRIEF DESCRIPTION OF THE DRAWINGS

FIG. 1 is a block diagram showing an overall construction of a defect reviewing apparatus according to Embodiment 1 of the present invention;

FIG. 2 is a schematic construction diagram showing an optical microscope portion of the defect reviewing apparatus according to Embodiment 1 of the present invention;

FIG. 3 is a schematic construction diagram showing a dark field illumination optical system according to Embodiment 1 of the present invention;

FIG. 4 is a flow diagram showing a defect reviewing process with the defect reviewing apparatus according to Embodiment 1 of the present invention;

FIG. 5 is a flow diagram showing a defect reviewing process with a defect reviewing apparatus according to Embodiment 2 of the present invention;

FIG. 6 is a diagram describing inspection modes applied depending on sizes of defects;

FIG. 7 is a flow diagram showing a defect reviewing process with a defect reviewing apparatus according to Embodiment 3 of the present invention;

FIG. 8 is a flow diagram showing a defect reviewing process with a defect reviewing apparatus according to Embodiment 4 of the present invention;

FIG. 9 is a diagram describing a search-around operation in a narrow field of view; and

FIG. 10 is a diagram describing a search-around operation in a wide field of view.

### DESCRIPTION OF THE EMBODIMENTS

### Embodiment 1

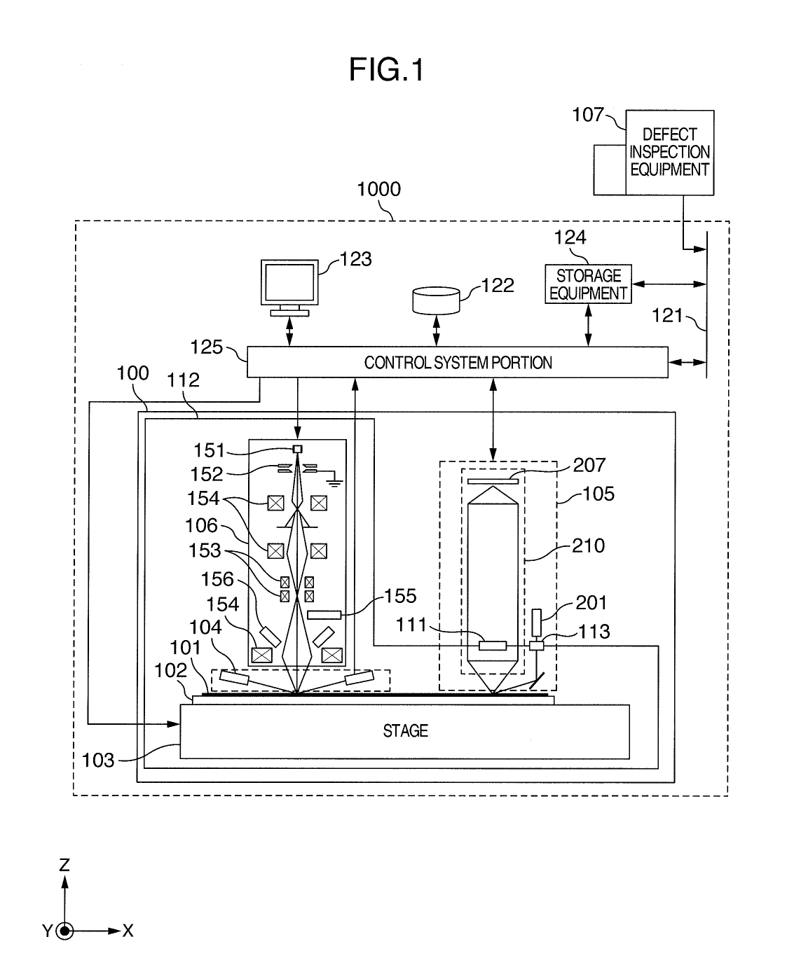

FIG. 1 is a construction diagram of a defect reviewing apparatus according to Embodiment 1 of the present invention. A defect reviewing apparatus 1000 includes in general a reviewing equipment 100, a network 121, a database 122, a user interface 123, a storage equipment 124, and a control system portion 125. Furthermore, the defect reviewing apparatus 1000 is connected via the network 121 to a defect inspecting equipment 107 as another inspection equipment.

The defect inspecting equipment 107 detects a defect that exists on a sample 101 and acquires defect information such as position coordinates and a size of the defect. The defect inspecting equipment 107 only needs to be one which can acquire information regarding a defect that exists on a sample 101.

The defect information acquired by the defect inspecting equipment 107 is input to the storage equipment 124 or the control system portion 125 via the network 121. The storage equipment 124 stores the defect information acquired by the defect inspecting equipment 107 and input via the network 121. The control system portion 125 controls the reviewing equipment 100 based on the defect information input from the defect inspecting equipment 107 or the defect information that is stored in the storage equipment 124 and read out therefrom. Some or all of the defects detected by the defect inspecting equipment 107 are then reviewed in detail so as to perform categorization of the defects, analysis of their causes, and the like.

Next, a construction of the reviewing equipment 100 shown in FIG. 1 will be described.

The reviewing equipment 100 is configured to include a drive section having a sample holder 102 and a stage 103, an optical height detector 104, an optical microscope portion 105, a vacuum chamber 112, an SEM 106 (electron microscope portion), and a laser displacement meter (not shown).

The sample 101 is placed on the sample holder 102 disposed on the stage 103 that is movable. The stage 103 moves the sample 101 placed on the sample holder 102 between the optical microscope portion 105 and the SEM 106. With movement of the stage 103, a defect to be reviewed can be placed in the field of view of the SEM 106 or in the field of view of the optical microscope portion 105.

The control system portion 125 is connected to the stage 103, the optical height detector 104, the optical microscope portion 105, the SEM 106, the user interface 123, the database 122, and the storage equipment 124, and controls operations and input/output of the respective components such as move of the stage 103, modulation of an illumination state, a lens configuration, and image acquisition conditions of the optical microscope portion 105, acquisition of an image and image acquisition conditions of the electron microscope portion 106, measurement and measurement conditions of the optical height detector 104, and the like. Also, the control system portion 125 is connected with a superordinate system (for example, the defect inspecting equipment 107) via the network 121.

The optical height detector 104 measures values corresponding to displacement of a surface of an area to be reviewed. Hereinafter, “displacement” includes various parameters such as a position of an area to be reviewed and an amplitude, a frequency, a period, and the like of its vibration. Specifically, the optical height detector 104 measures a height position of the surface of the area to be reviewed on the sample 101 present on the stage 103, and vertical vibration with referent to the surface of the area to be reviewed. “Displacement” and “vibration” measured with the optical height detector 104 are output as signals to the control system portion 125 and then fed back to a moving sequence of the stage 103.

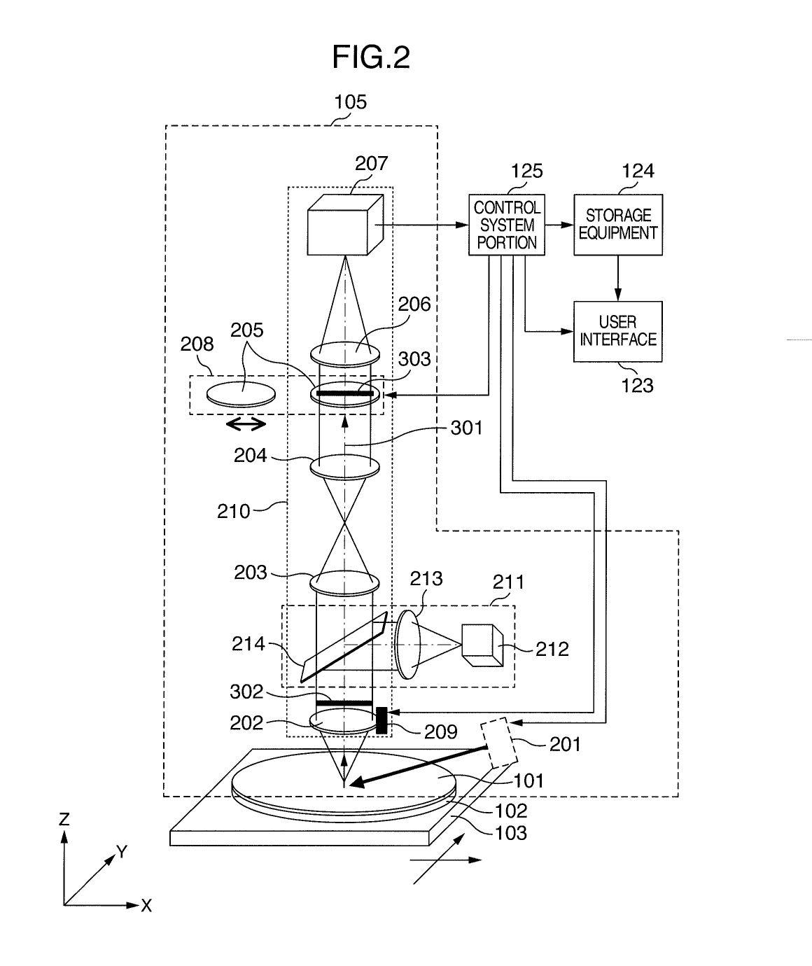

FIG. 2 shows a construction of the optical microscope portion 105. The optical microscope portion 105 is configured to include a dark field illumination optical system 201, a bright field illumination optical system 211, and a detection optical system 210. In FIG. 2, illustration of a vacuum chamber 112 and vacuum sealed windows 111 and 113 is omitted.

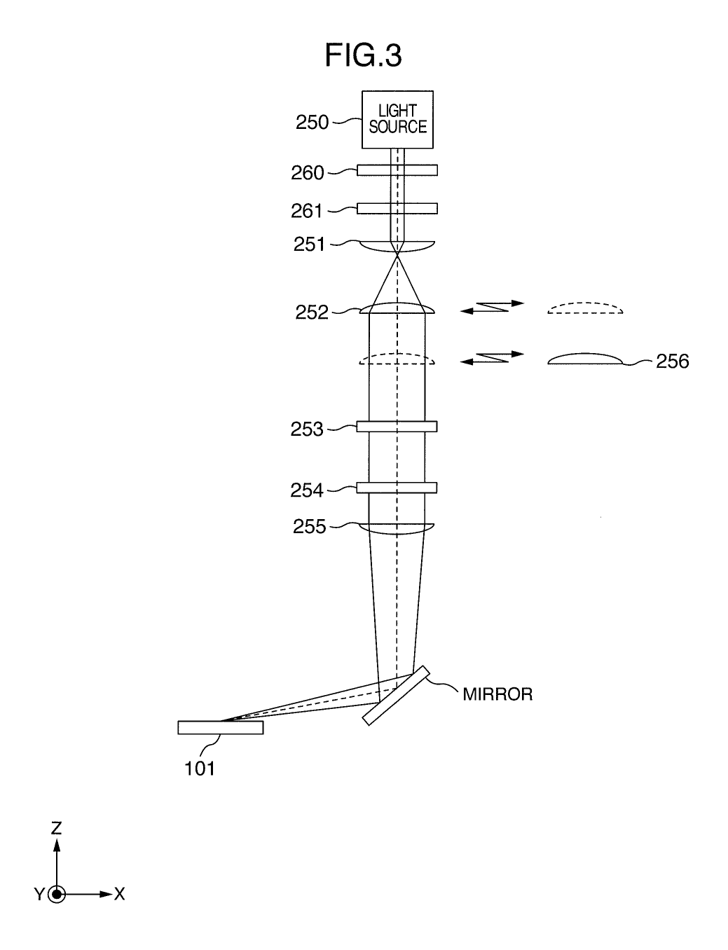

FIG. 3 is a schematic construction diagram showing the dark field illumination optical system 201. The dark field illumination optical system 201 is configured to include a light source 250, plano-convex lenses 251, 252, cylindrical lenses 253, 254, a condenser lens 255, a half wave plate 260, and an ND filter 261. A laser beam enters the sample 101 at an elevation angle of 10 degrees. The laser beam emitted from the light source 250 is converted into a collimated beam having a wide beam diameter through the plano-convex lenses 251, 252. Thereafter, the beam diameter is reduced only in the Y direction through the cylindrical lenses 253, 254 and it is focused on a nearly circular spot on the sample 101 through the condenser lens 255. The plano-convex lens 252 can be replaced with a plano-convex lens 256 having a different focal length in response to commands from the control system portion 125. The plano-convex lens 252 and the plano-convex lens 256 are equipped with respective driving mechanisms (not shown), which replace lenses. Also, the plano-convex lens 256 is disposed at a position according to its focal length so that the laser beam that transmits through the plano-convex lens 256 becomes a collimated beam when it is changed to the plano-convex lens 256. As a result, the laser spot diameter can be changed without changing the center position of the spot of the laser with which the sample 101 is irradiated. FIG. 3 shows an example in which the components from the light source 250 to the condenser lens 255 are disposed on a line; alternatively, reflection with a mirror may be utilized properly.

By rotating the half wave plate 260 polarization of illumination can be adjusted, and the laser power can be adjusted by the ND filter 261. In addition, the rotation angle of the half wave plate 260 and the transmissivity of the ND filter 261 can be controlled by the control system portion 125.

In the present embodiment, the explanation is given with a sample in which the illumination spot is change by replacing the plano-convex lens 252 with a lens having a different focal length; it should not, however, be limited with the replacement of the plano-convex lens. For example, the distance between lenses may be changed so as to change the illumination spot. With this, the number of lenses and the lens driving mechanisms can be reduced and space conservation becomes feasible.

In the present embodiment, the explanation is given with a sample in which two lenses having different focal lengths are switched with the other; however, the number of lenses is not limited to two. For example, a lens having an even shorter focal length may be prepared and one lens may be selected to be used from these three lenses. When a lens having an even shorter focal length is selected, an even wider illumination spot can be formed, and it becomes possible to prevent a defect from being overlooked.

In addition, the wavelength of the light source, the elevation angle of the illumination, the number of lenses, and the arrangement of the lenses are not limited to the example described in the present embodiment.

As shown in FIG. 2, the bright field illumination optical system 211 is configured to include a white light source 212, an illumination lens 213, a half mirror 214, and an objective lens 202. White illumination light emitted from the white light source 212 is converted into collimated light by the illumination lens 213. Then, by the half mirror 214, half of the collimated incident light is reflected in a direction parallel to the optical axis of the detection optical system 210, and is focused by the objective lens 202 on the area to be reviewed to irradiate. The half mirror 214 may be replaced with a dichroic mirror that allows more scattered light to transmit to a detector 207. Furthermore, in order that more scattered light generated on the surface of the sample 101 with illumination of the dark field illumination optical system 201 is caused to reach the detector 207, a construction may be adopted in which the half mirror 214 may be removed from the optical axis 301 when the bright field illumination optical system 211 is not used.

As shown in FIG. 2, the detection optical system 210 is configured to include the objective lens 202, lens systems 203, 204, a space distribution optical element 205, an imaging lens 206, and the detector 207. Reflected light and scattered light that are generated in the illuminated area on the sample 101 with illumination of the dark field illumination optical system 201 or the bright field illumination optical system 211 are collected by the objective lens 202 and an image is formed on the detector 207 through the lens systems 203, 204 and the imaging lens 206. The light with which an image is formed is converted into an electric signal by the detector 207 and then output to the control system portion 125. A signal processed in the control system portion 125 is stored in the storage equipment 124. Also, a processed result stored is displayed via the user interface 123.

The space distribution optical element 205 is disposed on a pupil surface 302 of the detection optical system 210 or on a pupil surface 303 on which an image is formed by the lens systems 203, 204 so as to shade with masking or control the polarizing direction of transmitting light to the light collected by the objective lens 202. The space distribution optical element 205 is, for example, a filter that transmits only polarized light in the X direction, a filter that transmits only polarized light in the Y direction, a filter that transmits only polarized light that vibrates radially with an optical axis 301 at the center, or the like. Alternatively, it may be a filter that masks scattered light that is generated due to surface roughness of the sample 101 or a filter that controls a polarization direction of transmission so as to cut scattered light that is generated due to surface roughness of the sample 101. A switching mechanism 208 selects a space distribution optical element 205 suitable to detect a target defect from a plurality of space distribution optical elements 205 having different optical characteristics and disposes it on the optical axis 301 of the detection optical system 210. The space distribution optical element 205 may not be disposed on the optical axis 301. In this case, a dummy substrate that changes the optical path length by the same length as the optical element 205 is disposed on the optical axis 301. The switching mechanism 208 can also switch over between the space distribution optical element 205 and the dummy substrate. For example, when the bright field observation is performed or there is no space distribution optical element 205 suitable for an object to be reviewed, the space distribution optical element 205 may cause an acquired image by the detector 207 to become disturbed. Thus, when the space distribution optical element 205 is not used, the dummy substrate can be disposed on the optical axis 301.

A height control mechanism 209 is used to align the surface to be reviewed on the sample 101 with the focal position of the detection optical system 210 in response to commands from the control system portion 125. As the height control mechanism 209, there are a linear stage, an ultrasonic motor, a piezo stage, and the like.

As the detector 207, there are a two-dimensional CCD sensor, a line CCD sensor, a TDI sensor group in which a plurality of TDIs are arranged in parallel, a photo diode array and the like. The detector 207 is disposed so that the sensor surface of the detector 207 is conjugated with the surface of the sample 101 or the pupil surface 302 of the objective lens 202.

When the illumination spot is changed by the dark field illumination optical system 201, the size of the image formed on the detector 207 is also decreased. In this case, pixels used in the detector 207 may be limited to those in an area around the center of the detector 207. For example, when the diameter of the illumination spot is decreased to a half, pixels of a quarter of the whole may be extracted. As a result, the amount of data to be transmitted and stored can be reduced.

When pixels used in the detector 207 are extracted, extraction may be conducted as measuring the position of the stage 103 with a laser displacement meter (not shown) and feeding back the measured result. Generally, the stop positioning accuracy of the stage 103 is lower than the measurement accuracy of the laser displacement meter. For example, when the stage 103 deviates from a desired stop position by +10 μm in the X direction, the extraction range of the pixels can be moved by 10 μm in the +X direction.

When the illumination spot is changed by the dark field illumination optical system 201, pixels used in the detector 207 may not be extracted, but the distance between the lenses in the lens systems 203, 204 may be changed so that the overall optical magnification of the detection optical system 210 is changed and thereby the imaging area of the detector 207 and the illumination spot are adjusted to nearly match with each other. Alternatively, the objective lens 202 may be replaced with an objective lens having a different magnification so that the overall optical magnification of the detection optical system 210 is changed and thereby the imaging area of the detector 207 and the illumination spot are adjusted to nearly match with each other. Further alternatively, the above two means may be combined together so as to change the magnification. As a result, the size of pixels can be adjusted to a proper scale according to the diameter of the illumination spot.

The control system portion 125 reads defect information that is output from the defect inspecting equipment 107 or defect information stored in the storage equipment 124, and controls the stage 103 based on the read defect information so that a defect to be reviewed enters the field of view of the optical microscope portion 105. Thereafter, based on an image detected with the optical microscope portion 105, a difference of defect coordinates between the defect inspecting equipment 107 and the reviewing equipment 100 is calculated and defect coordinate information stored in the storage equipment 124 is corrected.

The SEM 106 includes: an electron beam irradiation system having an electron beam source 151, an extraction electrode 152, a deflection electrode 153, an objective lens electrode 154; and an electron beam detection system having a secondary electron detector 155 and a backscattered electron detector 156. Primary electrons are emitted from the electron beam source 151 of the SEM 106, and the emitted primary electrons are extracted in a beam shape and accelerated by the extraction electrode 152. Thereafter, the trajectory of the primary electron beam accelerated by the deflection electrode 153 is controlled in the X and Y directions; the primary electron beam the trajectory of which is controlled is focused on the surface of the sample 101 to irradiate it with and scanned. Secondary electrons, backscattered electrons, and the others are generated from the surface of the sample 101 irradiated and scanned with the primary electron beam. The secondary electron detector 155 detects the produced secondary electrons, and the backscattered electron detector 156 detects electrons with relatively high energies such as backscattered electrons. A shutter (not shown) disposed on the optical axis of the SEM 106 can select start and stop of irradiation of the sample 101 with the electron beam emitted from the electron beam source 151.

Measurement conditions of the SEM 106 are controlled by the control system portion 125 so as to change acceleration voltage, focusing of the electron beam, and observation magnification. The SEM 106 reviews a defect in detail based on defect coordinate information corrected using an image captured by the optical microscope portion 105.

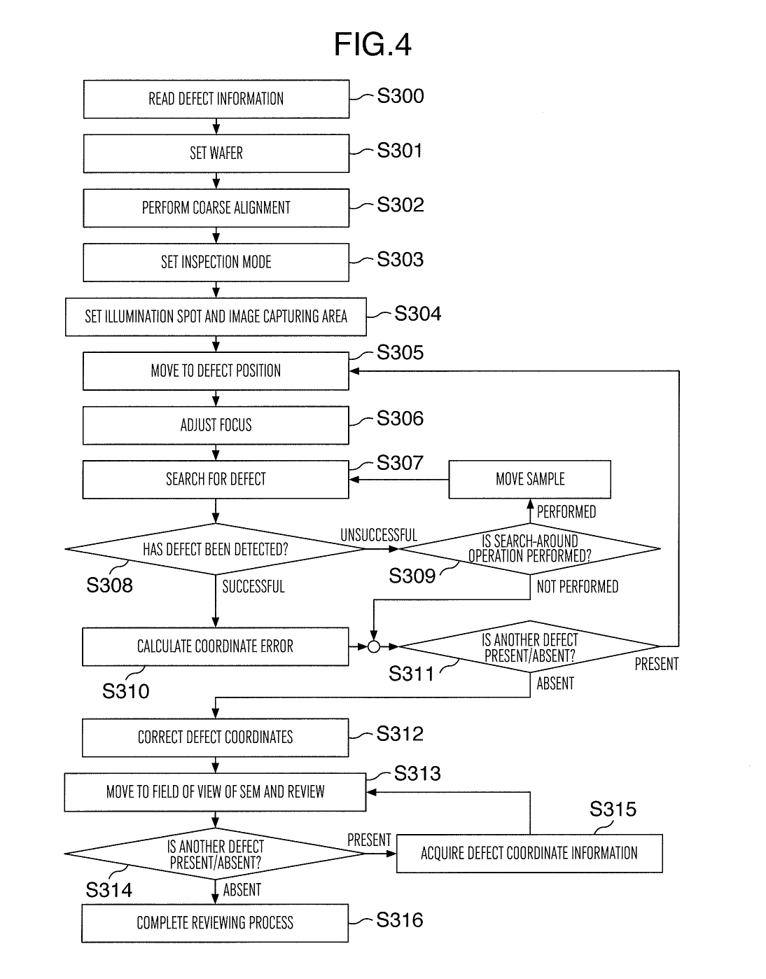

With reference to FIG. 4, a flow of reviewing a defect will be described.

S300: Information of defects that exist on a wafer and will be reviewed is read from other defect inspecting equipment 107.

S301: The wafer is set and secured by the sample holder 102.

S302: Coarse alignment is performed based on an image acquired by the detection optical system 210 while the sample 101 is illuminated by the bright field illumination optical system 211 of the optical microscope portion 105 or an image acquired by another alignment microscope (not shown) installed in the defect reviewing apparatus 1000.

S303: Thereafter, the user designates an inspection mode. When inspection is performed with a wide illumination spot to prevent a defect from being overlooked in detection, a wide field-of-view mode is selected; when inspection is performed with a narrow illumination spot to detect a defect in high sensitivity, a high sensitivity mode is selected. The inspection mode may be decided based on design data instead of user's designation. For example, when a wiring pitch is narrow and a critical defect size is small, the high sensitivity mode is set. In contrast, when the critical defect size is large, the wide field mode is set so as to prevent a defect from being overlooked.

S304: The configuration and positions of the lens of the dark field illumination optical system 201 are changed depending on the inspection mode selected at S303 so as to set the illumination spot. At the same time, when pixels used for the detector 207 are extracted, pixels to be used are restricted. Also, parameters necessary for acquiring an image such as laser power of illumination, polarizations, and a detection time period are set.

S305: The stage 103 is moved based on the defect information acquired with the other inspection device and stored in the storage equipment 124 so that the reviewing target enters the field of view of the optical microscope portion 105.

S306: The heights of the objective lens 202 of the optical microscope portion 105 and the stage 103 are adjusted with the height control mechanism 209 and the focal point of the optical microscope portion 105 is adjusted to the surface of the sample 101. When the focus is adjusted, laser is emitted from the dark field illumination optical system 201, a plurality of images are captured while the heights are changed, and characteristic amounts such as a defect area and a maximum luminance value are calculated for the plurality of images. For example, when the defect area is adopted as an evaluation value of focus adjustment, a point image of the defect becomes a minimum, when it is in focus; thus, a condition in which the area becomes a minimum is regarded to be in focus. Alternatively, when the maximum defect luminance value is adopted to be an evaluation value, since a luminance value of a point image of the defect becomes a maximum when it is in focus, a condition in which the luminance value becomes a maximum is regarded to be in focus. Otherwise, the luminance value and the defect area may be integrated together and an in-focus position may be calculated with them as evaluation values.

S307: An image of an area surrounding a defect to be reviewed is captured with the optical microscope portion 105 and the derived image is searched for a defect.

S308: It is determined whether a defect to be reviewed has been detected in the acquired image.

S310: When the detection of the defect has been successful (S308—successful), an error between coordinate data calculated with the optical microscope portion 105 and coordinate data calculated by the defect inspecting equipment 107 is calculated. For example, coordinate data can be obtained as the center of gravity of the defect image.

S309: When the detection of the defect has been unsuccessful (S308—unsuccessful), since it is conceivable that a defect may not be in the field of view, it is determined whether a search-around operation (search in peripheral portions around the first image-captured area) is performed. When the search-around operation is performed (S309—performed), the stage 103 is moved horizontally by a distance corresponding to the field view of the optical microscope portion 105 and the defect search is performed again.

S311: It is determined whether there remains a defect to be reviewed. If there is a defect to be reviewed (S311—present), the process returns to step 5305, and the same process is performed for a remaining target defect.

S312: When calculation of coordinate errors for all defects or defects designated by the user has been completed (S311—absent), the coordinate information acquired by the other inspection equipment is corrected to the coordinate information acquired with the optical microscope portion 105.

S313: The stage 103 is moved based on the corrected defect coordinates so that a defect is in the field of view of the SEM 106 and, thereafter, an SEM image is acquired.

S314: It is determined whether there remains a defect to be reviewed with the SEM.

S315: When there exists a defect to be reviewed (S314—present), coordinate information of the defect to be reviewed next is acquired and the SEM review is repeated.

S316: When all defects or the defects designated by the user have been completed with the SEM review (S314—absent), the defect review by the reviewing equipment 100 is completed.

Defect information read at 5300 is configured to include: defect inspection results detected using the defect inspecting equipment 107 which are constructed by any of defect coordinates, defect signals, defect sizes, defect shapes, polarization of scattered light by defects, species of defects, defect labels, characteristic amounts of defects, scattered signals of the surface of the sample 101, and the like, and combinations thereof; and defect inspection conditions of the defect inspecting equipment 107 which are constructed by any of an illumination incident angle, an illumination wavelength, an illumination azimuth, illumination intensity, illumination polarization, the azimuth and the elevation angle of the detector 207, the detection area of the detector 207, and the like, and combinations there. When the defect information acquired by the defect inspecting equipment 107 contains information of a plurality of detectors, defect information of the sample 101 that is output for each of the sensors or defect information of the sample 101 in which a plurality of sensor outputs are integrated is used.

In the above flow, the explanation is given with an example in which all defects are observed with the optical microscope portion 105 and their coordinate errors are corrected before they are reviewed with the SEM 106 is described; however, the present invention is not limited thereto. Alternatively, after coordinate information of one defect is corrected, the defect may be reviewed with the SEM and, thereafter, another defect may be detected with an optical microscope portion and then its coordinate information may be corrected and it may be reviewed with the SEM.

In the above flow, the explanation is given with an example in which the inspection mode is designated when the inspection starts and the inspection is conducted with the same inspection mode until the end; the present invention is, however, not to be limited thereto. Inspection modes may be designated for respective defects to be reviewed in advance and the inspection conditions may be changed for the respective defects.

When the detection of a defect has been unsuccessful in the first search-around operation, it is necessary to determine whether a second search-around operation is performed. Then, the total number of times a search-around operation is performed for one defect may be designated by the user, or may be calculated from a total time period allowable for a detailed review of one wafer.

### Embodiment 2

Next, Embodiment 2 will be described. Since a construction of a reviewing apparatus according to the present embodiment is the same as shown in FIGS. 1 to 3, its description will be omitted. The present embodiment is different from Embodiment 1 in that the inspection modes can be automatically set based on defect information.

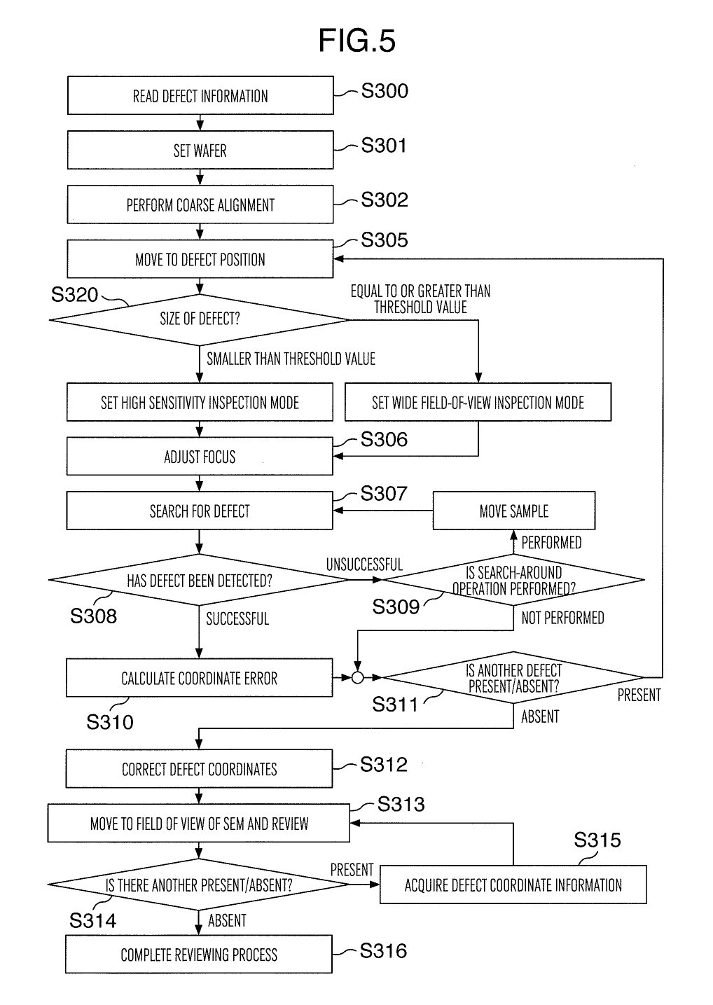

With reference to FIG. 5, a flow of a defect reviewing process according to Embodiment 2 will be described. Detailed description of the steps with the same reference numerals as those in FIG. 4 will be omitted.

S320: After reading defect information (S300), setting a wafer (S301), performing a coarse alignment (S302), and moving a defect in the field of view of the optical microscope portion 105 (S305), the size of a defect to be reviewed is determined. At this point, when the size of the defect to be reviewed is minute and smaller than a preset threshold (S320—smaller than threshold value), the high sensitivity inspection mode is automatically set. This means that the illumination spot is decreased in its size since a defect to be reviewed is small and it needs to be inspected with high sensitivity. In contrast, when the size of the defect is equal to or greater than the threshold value (S320—equal to or greater than threshold value), it is automatically set to the wide field inspection mode. When the size of a defect is large, since it is not necessary to decrease the size of the illumination spot, the inspection is performed with a wide illumination spot so as to prevent the defect from being overlooked. In addition, parameters necessary to capture an image such as the illumination laser power, the polarization, the detection time period, and so forth are also set.

Since the flow hereunder are the same as those shown in FIG. 4, its description will be omitted.

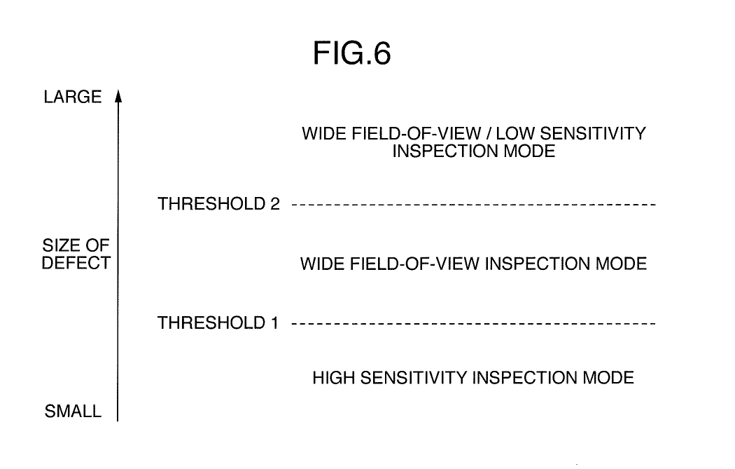

In FIG. 5, the explanation is given with an example in which two inspection modes are switched over according to a threshold value; however, the present invention is not limited thereto. For example, as shown in FIG. 6, two threshold values may be set (Threshold 1<Threshold 2) and the inspection modes may be changed according to the threshold values. When the size of a defect is smaller than Threshold 1, the high sensitivity inspection mode is set. When the size of the defect is greater than Threshold 1 and smaller than Threshold 2, the wide field-of-view inspection mode is set. When the size of the defect is greater than Threshold 2, a wide field-of-view/low sensitivity inspection mode is set in which the illumination spot is the same as that in the wide field-of-view inspection mode and laser power is lowered. For example, when a giant defect is reviewed, since the amounts of reflected and scattered light from the defect are very large, an image acquired by the detector 207 becomes saturated, and the coordinates of the defect cannot be accurately calculated. To prevent such a problem, the illumination spot is increased in its size and the laser power is lowered so that the detector 207 won't be saturated even for a giant defect and the coordinates of the defect can be accurately obtained.

When a plurality of defects to be reviewed exist in the same field, an inspection mode can be set based on the smallest defect.

In the present embodiment, the explanation is given with a sample in which inspection modes are set according to the defects. When the inspection mode is changed over, the lens configuration of the dark field illumination optical system 201 needs to be changed, and a driving time period and a lens settling time period for lenses are required for every lens replacement. Thus, in order to minimize the number of times of the lens replacement and to shorten the total inspection time period, the order in which defects are reviewed may be set in advance based on the defect information stored in the storage equipment 124. For example, defects of sizes equal to or greater than a threshold value may be reviewed first and, thereafter, the lenses may be replaced and defects of sizes smaller than the threshold value may be reviewed. Of course, defects of sizes smaller than the threshold value may be reviewed first and, thereafter, defects of sizes equal to or greater than the threshold value may be reviewed. Furthermore, the order in which defects are reviewed may be set so that the moving distance of the stage 103 becomes a minimum.

### Embodiment 3

Next, Embodiment 3 according to the present invention will be described. Since a construction of a reviewing apparatus according to the present embodiment is the same as shown in FIGS. 1 to 3, its description will be omitted. The present embodiment is different from Embodiment 1 in that the inspection method in repeated search after the first detection of a defect has been unsuccessful in the optical microscope portion.

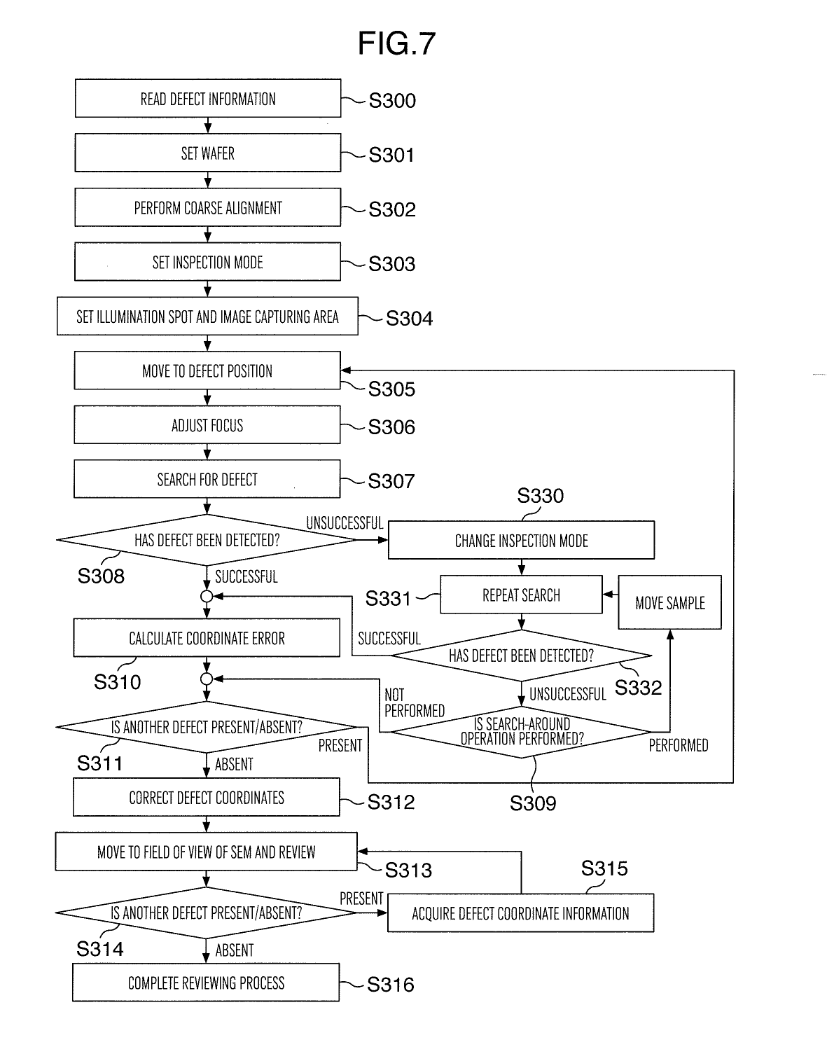

With reference to FIG. 7, a flow of a defect reviewing process according to Embodiment 3 will be described. Since the steps from reading the defect information (S300) to searching for a defect (S307) are the same as those shown in FIG. 4, their description will be omitted.

S330: When the defection of the defect has been unsuccessful (S308 unsuccessful), the inspection mode is changed. An explanation is given for the case where the high sensitivity inspection mode has been set, for example, at the time of inspection mode setting (S303). When the detection of the defect has been unsuccessful in the high sensitivity inspection mode, since the illumination spot is small, it is conceivable that the defect to be reviewed would not have been contained within the field of view and thereby the detection of the defect would have been unsuccessful. Therefore, in order to facilitate the defect to fit easily in the field of view, the illumination spot is increased in its size.

S331: The inspection mode is changed and the search is performed again.

S332: It is determined whether the detection of the defect to be reviewed in an acquired image in the repeated search has been successful. When the detection of the defect has been successful as a result of the repeated search (S332—successful), an error of the defect coordinates is calculated. When the detection of the defect has been unsuccessful (S332—unsuccessful), it is determined whether a search-around operation is performed (S309).

Since the rest of the flow is the same as that shown in FIG. 4, its description will be omitted.

When the detection of a defect has been unsuccessful as the wide field-of-view inspection mode is set at the inspection mode setting (S303), possibility of unsuccessful defect detection due to in sufficient luminance is conceivable and, thus, the illumination spot is decreased in its size so as to increase the luminance and the search is repeated. As a result, the defect detection success rate in the repeated searching operation can be improved.

According to the present embodiment, the explanation is given with an example in which the user sets an inspection mode and the inspection mode is changed at the time of repeated search; however, the present invention is not limited thereto. For example, it may be combined with Embodiment 2 to set the inspection mode automatically so that the inspection mode is changed when the detection of a defect has been unsuccessful in a first attempt and the search is then repeated. Also, the inspection modes may not necessarily be limited to two of the high sensitivity inspection mode and the wide field-of-view inspection mode.

As for a repeated search, the inspection mode may be changed when a particular condition is satisfied. For example, the inspection mode may be changed only when the size of the defect turns out to be smaller than a predetermined threshold value.

### Embodiment 4

Next, Embodiment 4 according to the present invention will be described. Since a construction of a reviewing apparatus according to the present embodiment is the same as shown in FIGS. 1 to 3, its description will be omitted. In Embodiment 3, an example in which the inspection mode is changed over and then the search is repeated at the time of unsuccessful defect detection is described. In Embodiment 4, it is different from Embodiment 3 in that the inspection mode is changed when a search-around operation is performed after a repeated search turned out to be unsuccessful.

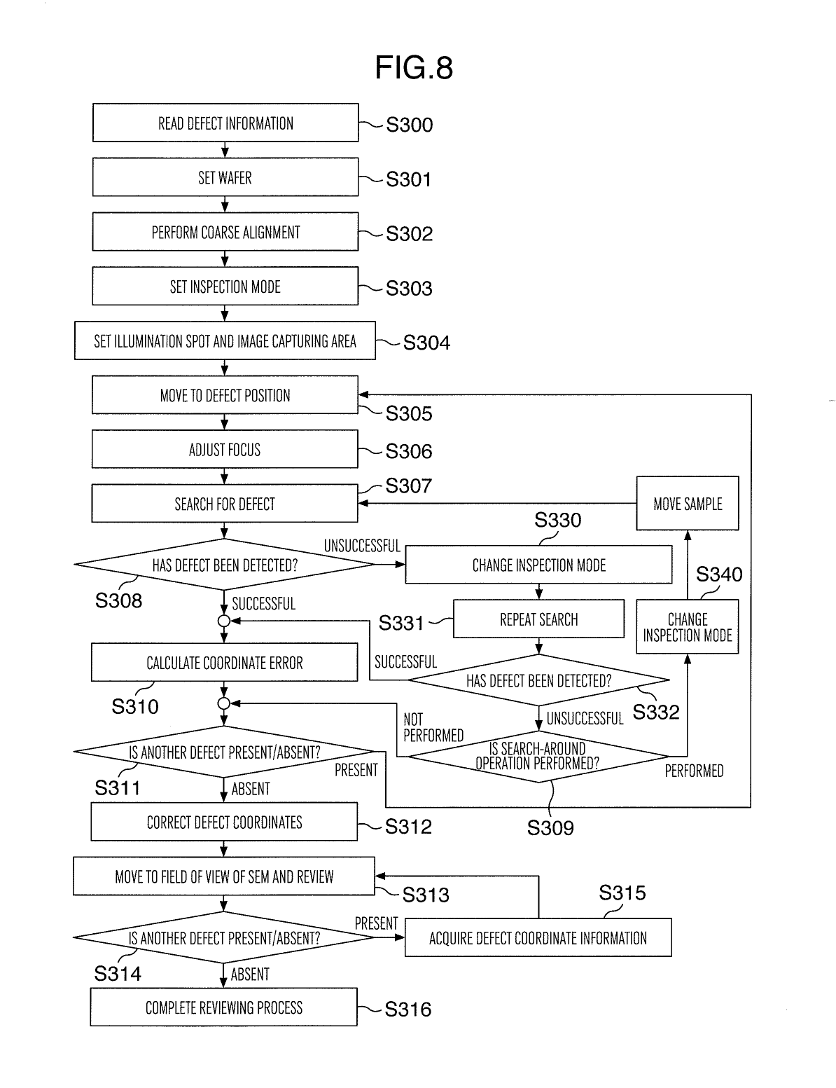

With reference to FIG. 8, a flow of a defect reviewing process according to the present embodiment will be described. Since the steps from reading the defect information (S300) to changing the inspection mode (S330) and performing the search-around operation (S309) are the same as those shown in FIG. 7, their description will be omitted.

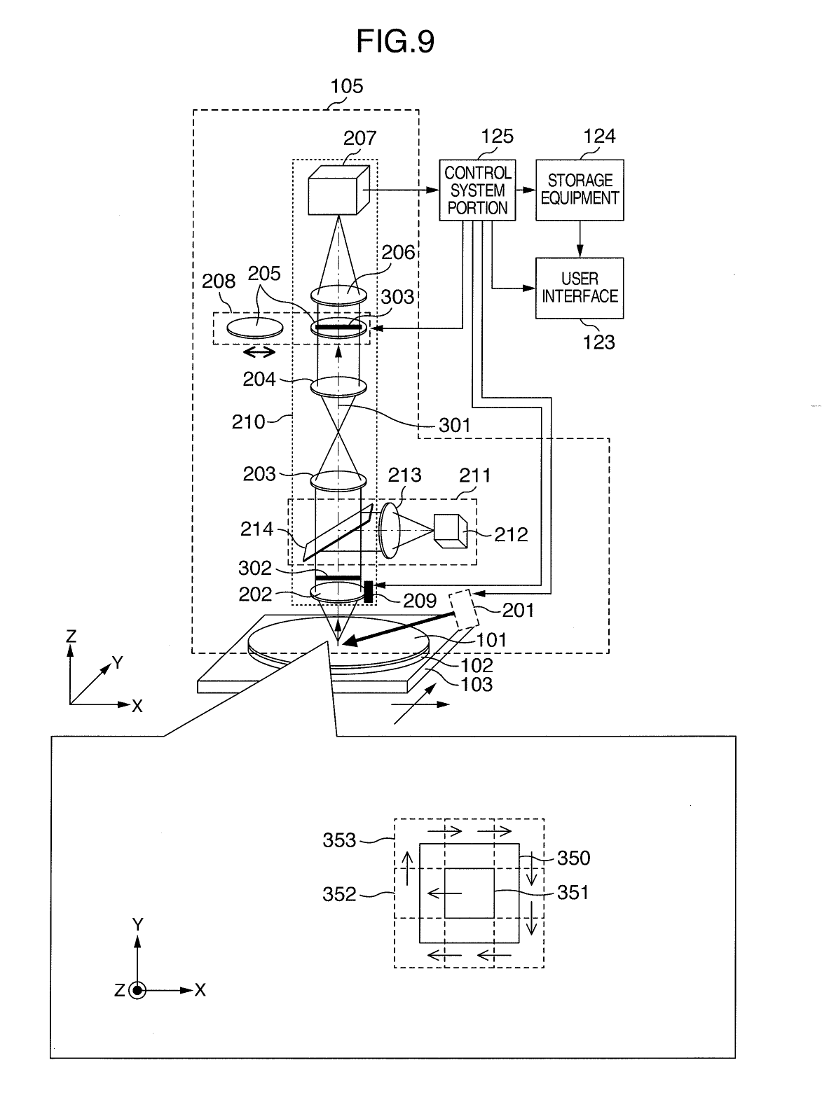

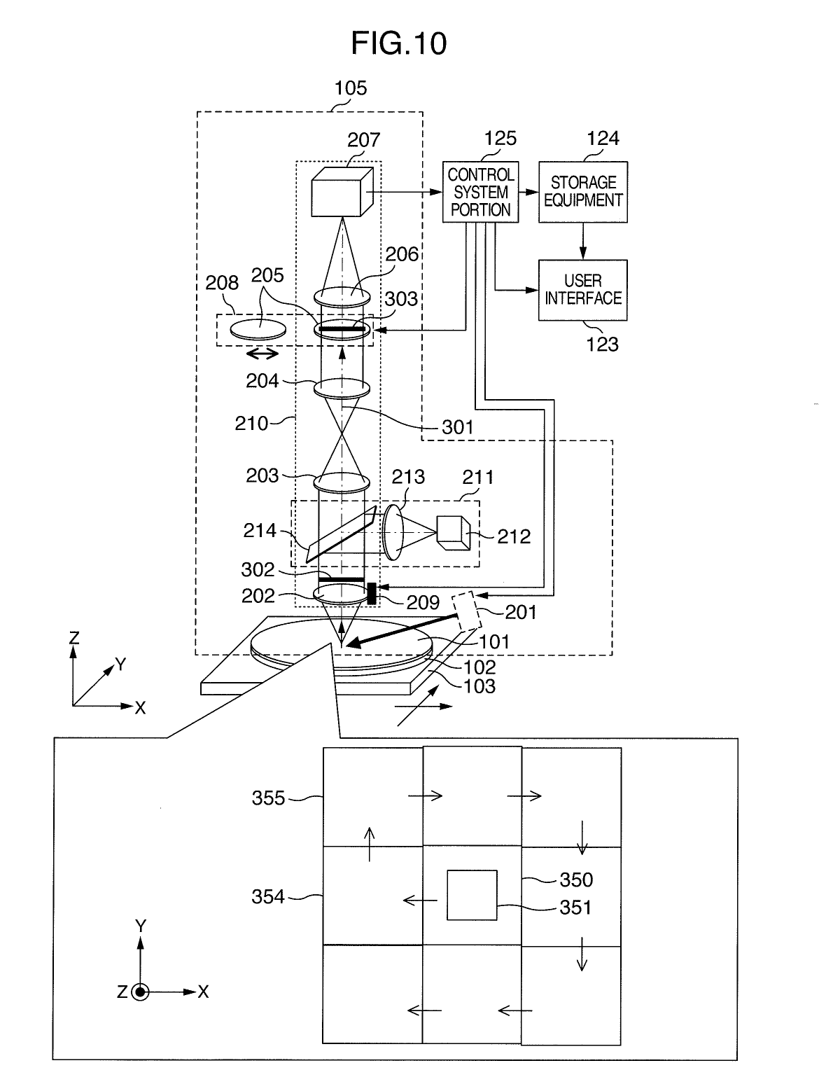

S340: When the search-around operation is performed (S309—performed), the inspection mode is changed and the sample 101 is moved. An explanation is given for the case where the wide field-of-view inspection mode has been set, for example, at the time of inspection mode setting (S303). In this case, a repeated search is performed in the high sensitivity inspection mode (S331) and it is changed over to the wide field-of-view inspection mode to further conduct the sample movement. FIG. 9 shows sizes of the fields of view in respective inspection modes in the sample 101 and position relations of the fields of view when the search-around operation is performed. First, it is set to the wide field-of-view inspection mode and an image of an area 350 on the sample is acquired. When the detection of a defect has been unsuccessful in this condition, the illumination spot is decreased in its size and an image of an area 351 is acquired. Then, when the search-around operation is performed still in the high sensitivity inspection mode, images of peripheral areas are acquired as an area 352 to an area 353 and so forth as shown in FIG. 9. However, since the field of view is narrow in the high sensitivity inspection mode, it could take longer time to search for a defect. Thus, it is changed over to the wide field-of-view inspection mode and images of peripheral areas are acquired as an area 354 to area 355 and so forth as shown in FIG. 10. As a result, a wider area can be searched and the time period taken for the search-around operation can be reduced.

Although an example is described in which the wide field-of-view inspection mode has been initially set in the present embodiment, the similar process may be performed even when it has been set initially to the high sensitivity inspection mode.

In the present embodiment, an example in which the user sets the inspection mode is described; however, the present embodiment is not limited thereto, and the inspection mode may be automatically set as being combined with Embodiment 2.

As stated above, the present invention devised by the present inventors have been specifically described based of the embodiments; however, the present invention is not limited to the foregoing embodiments and various modifications are possible in a scope without departing from the spirit thereof.

1. A defect reviewing apparatus, comprising:
an illumination optical system that irradiates a sample with laser, inspection modes being switched over in the illumination optical system based on defect information acquired in another inspection equipment;
a detection optical system that detects reflected light or scattered light from the sample;
a processing portion that calculates coordinates of a defect based on the reflected light or scattered light detected by the detection optical system; and
an electron microscope that reviews the defect based on the coordinates of the defect calculated by the processing portion.

2. The defect reviewing apparatus according to claim 1, wherein a size of an illumination spot of the laser with which the sample is irradiated is changed in the illumination optical system based on defect information acquired in another inspection equipment.

3. The defect reviewing apparatus according to claim 2, wherein a size of an illumination spot of the laser with which the sample is irradiated is changed in the illumination optical system based on size information of a defect acquired in another inspection equipment.

4. The defect reviewing apparatus according to claim 3, wherein a size of an illumination spot of the laser with which the sample is irradiated is changed by replacement of or change in a distance between lenses, which the illumination optical system comprises.

5. The defect reviewing apparatus according to claim 3, wherein pixels of a detector that detects the reflected light or scattered light in the detection optical system depend on a size of an illumination spot of the laser according to the illumination optical system.

6. The defect reviewing apparatus according to claim 5, wherein the pixels of the detector are adjusted in the detection optical system based on a measurement result of a laser displacement meter.

7. The defect reviewing apparatus according to claim 3, wherein an optical magnification of the detection optical system is changed according to a size of the illumination spot.

8. The defect reviewing apparatus according to claim 3, wherein an intensity of the laser of the illumination optical system is changed based on size information of a defect acquired in another inspection equipment.

9. The defect reviewing apparatus according to claim 1, wherein a size of an illumination spot is changed when the processing portion determines that detection results of a defect satisfy predetermined conditions.

10. A defect reviewing method, comprising the steps of:
irradiating a sample with laser, inspection modes are switched over in the irradiating based on defect information acquired in another inspection equipment;
detecting reflected light or scattered light from the sample;
calculating coordinates of a defect based on the reflected light or scattered light detected at the detecting; and
reviewing a defect based on the coordinates of the defect calculated at the calculating.

11. The defect reviewing method according to claim 10, wherein a size of an illumination spot of the laser with which the sample is irradiated is changed in the irradiating based on defect information acquired in another inspection equipment.

12. The defect reviewing method according to claim 11, wherein a size of an illumination spot of the laser with which the sample is irradiated is changed in the irradiating based on size information of a defect acquired in another inspection equipment.

13. The defect reviewing method according to claim 12, wherein a size of an illumination spot of the laser with which the sample is irradiated is changed in the irradiating by replacement of a lens or change in a distance between lenses.

14. The defect reviewing method according to claim 12, wherein pixels of a detector that detects the reflected light or scattered light in the detecting depend on a size of an illumination spot of the laser in the irradiating.

15. The defect reviewing method according to claim 14, wherein the pixels of the detector are adjusted in the detecting based on a measurement result of a laser displacement meter.

16. The defect reviewing method according to claim 12, wherein an optical magnification of the detecting is changed according to a size of the illumination spot.

17. The defect reviewing method according to claim 12, wherein an intensity of the laser of the illumination optical system is changed in the irradiating based on size information of a defect acquired in another inspection equipment.

18. The defect reviewing method according to claim 11, wherein a size of an illumination spot is changed when it is determined in the processing that detection results of a defect satisfy predetermined conditions.
